(19) United States
(12) Patent Application Publication
(10) Pub. No.: US 2026/0150298 A1
(43) Pub. Date: May 28, 2026

(54) SEMICONDUCTOR DEVICE

(71) Applicant: Samsung Electronics Co., Ltd., Suwon-si (KR)

(72) Inventors: Youngkeol KIM, Suwon-si (KR); Hyukjun KWON, Suwon-si (KR); JUNHO PARK, Suwon-si (KR); Jiwon SEO, Suwon-si (KR); MANJIN EOM, Suwon-si (KR); JUNGHWAN PARK, Suwon-si (KR); Jinho PARK, Suwon-si (KR); Jong-Hyuk LEE, Suwon-si (KR); MYOUNGKWAN CHAE, Suwon-si (KR); Wonhyeok HEO, Suwon-si (KR)

(21) Appl. No.: 19/265,035

(22) Filed: Jul. 10, 2025

(30) Foreign Application Priority Data
Nov. 28, 2024 (KR) 10-2024-0174033

(51) Int. Cl. H10B 61/00; H10N 50/01; H10N 50/10

(52) U.S. Cl. CPC H10B 61/10; H10N 50/01; H10N 50/10

(57) ABSTRACT

A semiconductor device may include a lower insulating layer on a substrate, a data storage pattern disposed on the lower insulating layer, a cell insulating layer disposed on the lower insulating layer to cover the data storage pattern, a cell conductive line disposed on the data storage pattern, and a capping insulating layer interposed between a side surface of the data storage pattern and the cell insulating layer. The cell conductive line may include a first portion adjacent to the data storage pattern and a second portion on the first portion, and the capping insulating layer may be extended to a side surface of the first portion.

### CROSS-REFERENCE TO RELATED APPLICATIONS

This U.S. non-provisional patent application claims priority under 35 U.S.C. § 119 to Korean Patent Application No. 10-2024-0174033, filed on Nov. 28, 2024, in the Korean Intellectual Property Office, the entire contents of which are hereby incorporated by reference.

### BACKGROUND OF THE INVENTION

The present disclosure relates to a semiconductor device and a method of fabricating the same, and in particular, to a semiconductor device including a magnetic tunnel junction and a method of fabricating the same.

As the demand for electronic devices with increased speed and/or reduced power consumption increases, the demand for semiconductor memory devices with faster operating speeds and/or lower operating voltages is increasing. A magnetic memory device has been proposed to satisfy such a demand. The magnetic memory device has technical advantages, such as reduced latency and/or non-volatility, and thus, it is emerging as a next-generation semiconductor memory device.

In general, the magnetic memory device includes a magnetic tunnel junction (MTJ) pattern. The MTJ pattern includes two magnetic layers and an insulating layer interposed therebetween. Resistance of the MTJ pattern may vary depending on magnetization directions of the magnetic layers. For example, the electric resistance of the MTJ pattern is higher when magnetization directions of the magnetic layers are anti-parallel to each other than when they are parallel to each other. Such a difference in electric resistance can be used for data storing/reading operations of the magnetic memory device.

An embedded structure of the magnetic memory device, in which the MTJ pattern is disposed between metal lines, is being developed to meet various demands for the electronics industry.

### SUMMARY

An embodiment of the inventive concept provides a method of reducing a process defect in a process of fabricating a semiconductor device and a semiconductor device fabricated thereby.

An embodiment of the inventive concept provides a semiconductor device with improved electrical characteristics and a method of fabricating the same.

According to an embodiment of the inventive concept, a semiconductor device may include a lower insulating layer on a substrate, a data storage pattern disposed on the lower insulating layer, a cell insulating layer disposed on the lower insulating layer to cover the data storage pattern, a cell conductive line disposed on the data storage pattern, and a capping insulating layer interposed between a side surface of the data storage pattern and the cell insulating layer. The cell conductive line may include a first portion adjacent to the data storage pattern and a second portion on the first portion, and the capping insulating layer may be extended to a side surface of the first portion.

According to an embodiment of the inventive concept, a semiconductor device may include a lower insulating layer on a substrate, a data storage pattern disposed on the lower insulating layer, a cell insulating layer disposed on the lower insulating layer to cover the data storage pattern, a cell conductive line disposed on the data storage pattern, and a capping insulating layer interposed between a side surface of the data storage pattern and the cell insulating layer. The cell conductive line may include a first portion adjacent to the data storage pattern and a second portion on the first portion. A width of the first portion in a first direction may decrease as a distance from the substrate increases, and a width of the second portion in the first direction may increase as a distance from the substrate increases. The first direction may be parallel to a top surface of the substrate.

According to an embodiment of the inventive concept, a semiconductor device may include a substrate including a cell region and a peripheral region, a first lower insulating layer disposed on the cell region and extended to the peripheral region, a second lower insulating layer disposed on the first lower insulating layer on the cell region and extended to the first lower insulating layer on the peripheral region, data storage patterns disposed on the second lower insulating layer on the cell region and spaced apart from each other a first direction and a second direction, which are parallel to a top surface of the substrate and are not parallel to each other, cell conductive lines disposed on the data storage patterns, respectively, which are spaced apart from each other in the first direction, a cell insulating layer disposed on the second lower insulating layer on the cell region to cover the data storage patterns, a capping insulating layer interposed between a side surface of each of the data storage patterns and the cell insulating layer, a peripheral insulating layer disposed on the second lower insulating layer on the peripheral region, the peripheral insulating layer including a material different from the cell insulating layer, and a peripheral conductive contact disposed in the peripheral insulating layer to penetrate the first and second lower insulating layers on the peripheral region. Each of the cell conductive lines may include a first portion adjacent to each of the data storage patterns and a second portion on the first portion, and the capping insulating layer may be extended to a side surface of the first portion.

### BRIEF DESCRIPTION OF THE DRAWINGS

FIG. 1 is a circuit diagram illustrating a unit memory cell of a semiconductor device according to an example embodiment of the inventive concept.

FIG. 2 is a plan view illustrating a semiconductor device according to an example embodiment of the inventive concept.

FIG. 3 is a sectional view taken along a line A-A′ of FIG. 2.

FIGS. 4A and 4B are sectional views, each of which illustrates a magnetic tunnel junction pattern of a semiconductor device according to an example embodiment of the inventive concept.

FIGS. 5A and 5B are enlarged sectional views illustrating a portion P of FIG. 3.

FIGS. 6 to 15 are sectional views, which are taken along a line A-A′ of FIG. 2 to illustrate a method of fabricating a semiconductor device according to an example embodiment of the inventive concept.

### DETAILED DESCRIPTION

Example embodiments of the inventive concepts will now be described more fully with reference to the accompanying drawings, in which example embodiments are shown. Like reference characters refer to like elements throughout.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

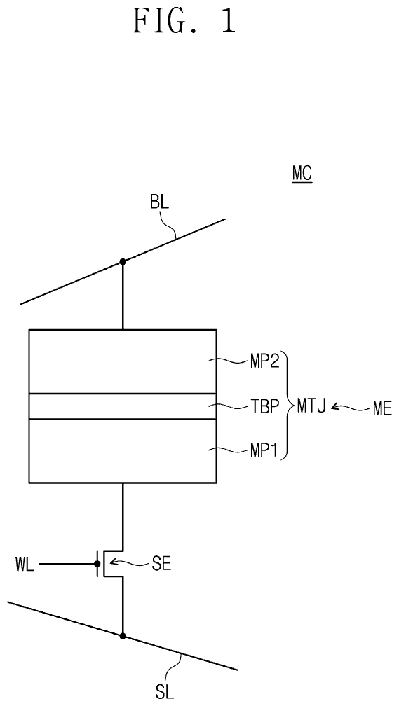

FIG. 1 is a circuit diagram illustrating a unit memory cell of a semiconductor device according to an example embodiment of the inventive concept.

Referring to FIG. 1, a unit memory cell MC may include a memory element ME and a selection element SE. The memory element ME and the selection element SE may be electrically connected to each other in series. The memory element ME may be provided between, and connected to, a bit line BL and the selection element SE. The selection element SE may be provided between, and connected to, the memory element ME and a source line SL and may be controlled by a word line WL. The selection element SE may include, for example, a bipolar transistor or a metal-oxide-semiconductor (MOS) field effect transistor.

The memory element ME may include a magnetic tunnel junction pattern MTJ including magnetic patterns MP1 and MP2, which are spaced apart from each other, and a tunnel barrier pattern TBP, which is interposed between the magnetic patterns MP1 and MP2. One of the magnetic patterns MP1 and MP2 may have a fixed magnetization direction, regardless of an external magnetic field generated under a typical user condition, and thus, it may serve as a reference magnetic pattern of the magnetic tunnel junction pattern MTJ. The other of the magnetic patterns MP1 and MP2 may have a magnetization direction, which can be changed to one of two stable magnetization directions by an external magnetic field, and thus, it may serve as a free magnetic pattern of the magnetic tunnel junction pattern MTJ. The electric resistance of the magnetic tunnel junction pattern MTJ may be much greater when the magnetization directions of the reference and free magnetic patterns are antiparallel to each other than when they are parallel to each other. This means that the electrical resistance of the magnetic tunnel junction pattern MTJ can be controlled by changing the magnetization direction of the free magnetic pattern. Thus, a difference in electric resistance of the magnetic tunnel junction pattern MTJ, which is caused by a difference in magnetization direction between the reference and free magnetic patterns, may be used to change data that is stored in the memory element ME of the unit memory cell MC.

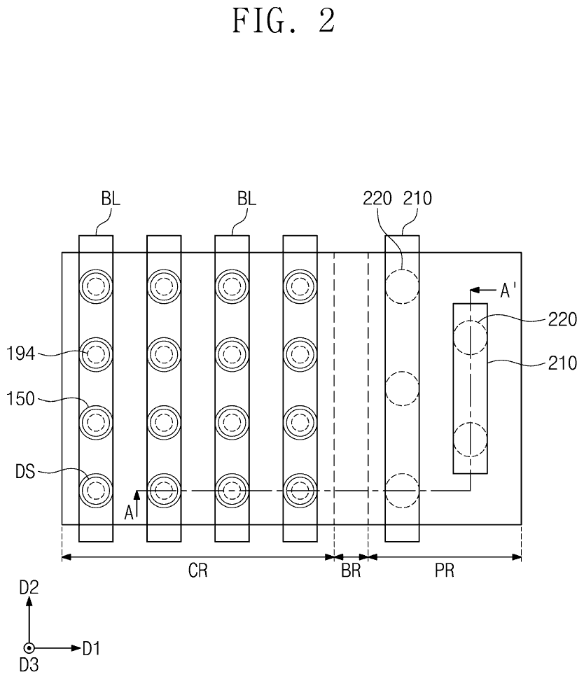

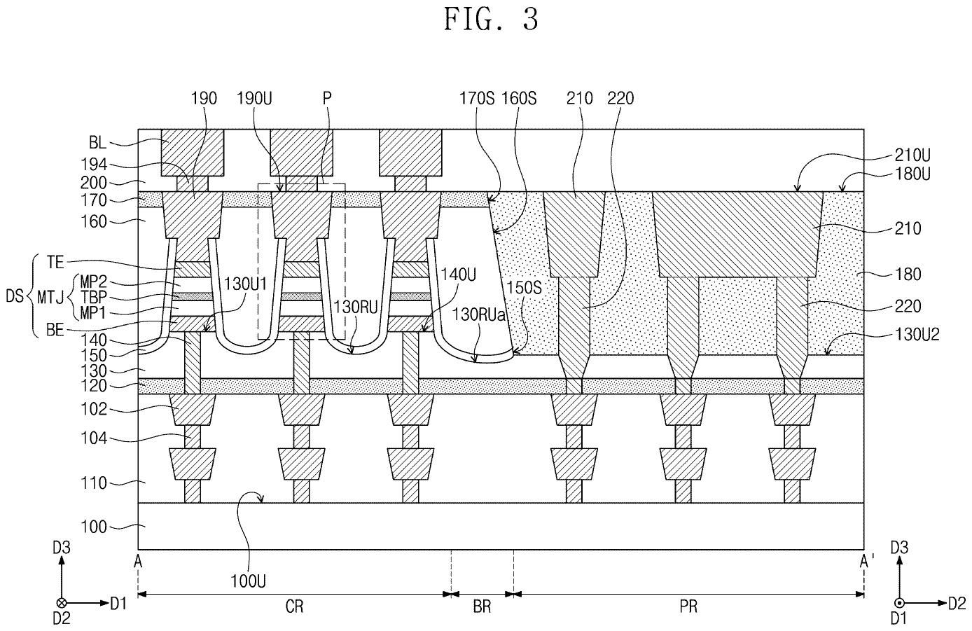

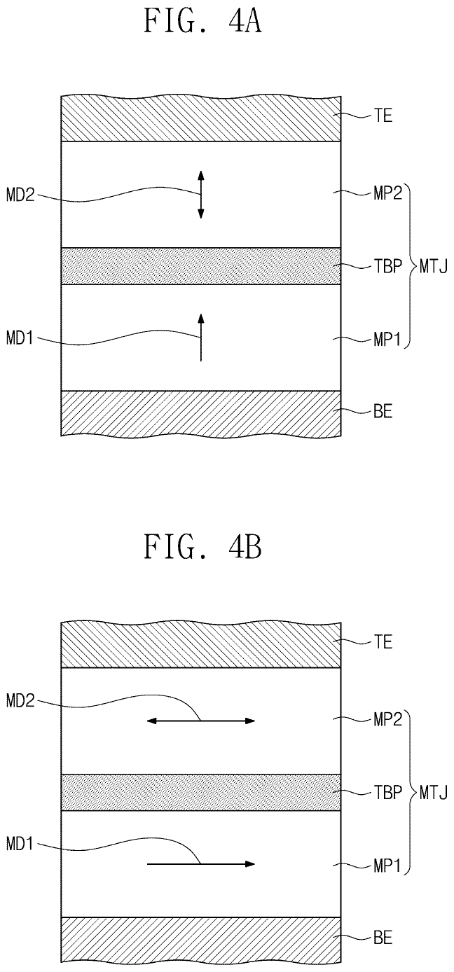

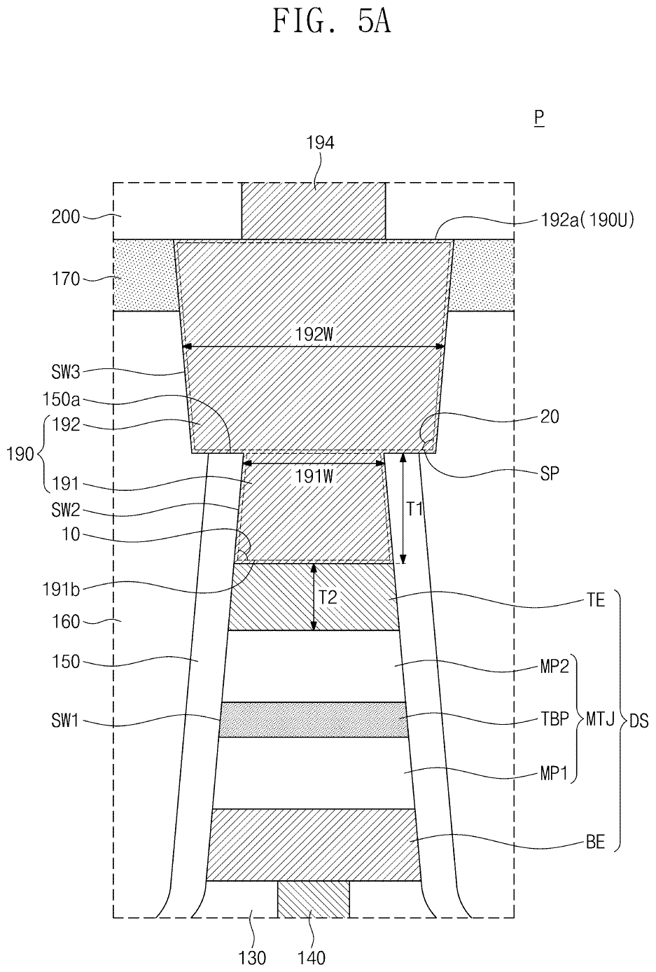

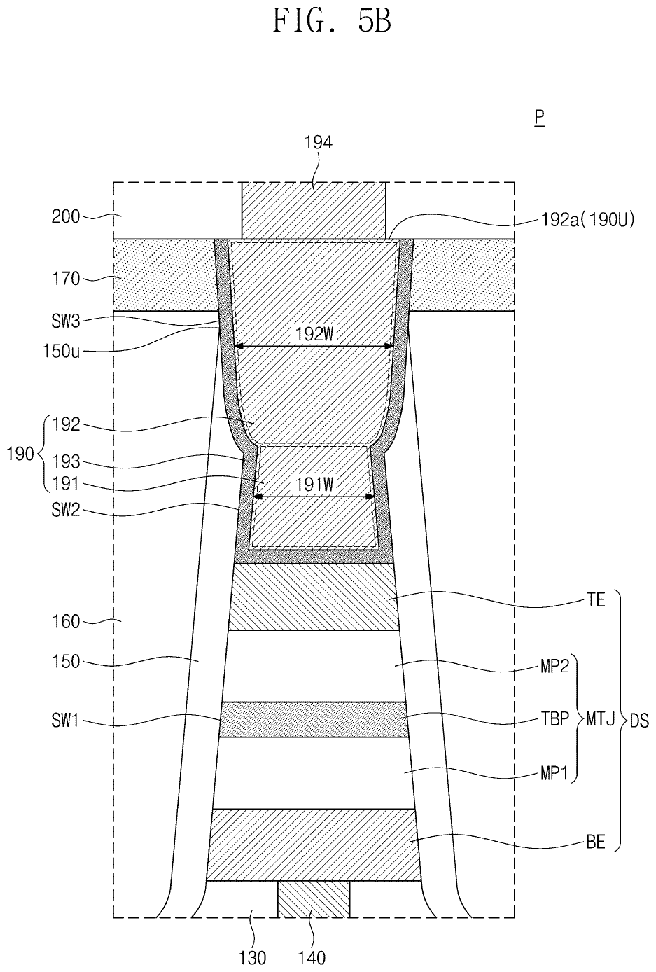

FIG. 2 is a plan view illustrating a semiconductor device according to an example embodiment of the inventive concept. FIG. 3 is a sectional view taken along a line A-A′ of FIG. 2. FIGS. 4A and 4B are sectional views, each of which illustrates a magnetic tunnel junction pattern of a semiconductor device according to an example embodiment of the inventive concept. FIGS. 5A and 5B are enlarged sectional views illustrating a portion P of FIG. 3.

Referring to FIGS. 2 and 3, a substrate 100 including a cell region CR, a peripheral region PR, and a boundary region BR therebetween may be provided. The substrate 100 may be a semiconductor substrate (e.g., a silicon wafer, a silicon-on-insulator (SOI) wafer, a silicon germanium wafer, a germanium wafer, or a gallium arsenic wafer). The cell region CR may be a region of the substrate 100 provided with the memory cells MC of FIG. 1, and the peripheral region PR may be another region of the substrate 100, in which peripheral circuits for driving the memory cells MC are provided. The boundary region BR may be other region of the substrate 100 provided between the cell region CR and the peripheral region PR.

Interconnection structures 102 and 104 may be disposed on the substrate 100. The interconnection structures 102 and 104 may be disposed on the cell region CR and the peripheral region PR of the substrate 100. The interconnection structures 102 and 104 may include interconnection lines 102, which are vertically spaced apart from the substrate 100, and interconnection contacts 104, which are connected to the interconnection lines 102. The interconnection lines 102 may be spaced apart from a top surface 100U of the substrate 100 in a vertical direction D3 perpendicular to a top surface 100U of the substrate 100. In the present specification, a first direction D1 and a second direction D2 may be parallel to the top surface 100U of the substrate 100 and may not be parallel to each other. A third direction D3 may be perpendicular to the top surface 100U of the substrate 100 and may be referred to as the vertical direction D3. In an embodiment, the first to third directions D1, D2, D3 may be orthogonal to each other.

The interconnection contacts 104 may be disposed between the substrate 100 and the interconnection lines 102. Each of the interconnection lines 102 may be electrically connected to the substrate 100 through a corresponding one of the interconnection contacts 104. The interconnection lines 102 and the interconnection contacts 104 may be formed of or include at least one of metallic materials (e.g., copper).

The selection elements SE of FIG. 1 may be disposed on the cell region CR of the substrate 100, and peripheral transistors, which constitute the peripheral circuits, may be disposed on the peripheral region PR of the substrate 100. The selection elements SE and the peripheral transistors may be, for example, field effect transistors. Each of the interconnection lines 102 may be electrically connected to a corresponding one of terminals (e.g., source, drain, and gate terminals) of the selection elements or peripheral transistors through a corresponding one of the interconnection contacts 104.

An interconnection insulating layer 110 may be disposed on the substrate 100 to cover the interconnection structures 102 and 104. The interconnection insulating layer 110 may be disposed on the cell region CR of the substrate 100 and may be extended to the boundary and peripheral regions BR and PR of the substrate 100. The interconnection insulating layer 110 may be provided to expose top surfaces of the uppermost ones of the interconnection lines 102. In an embodiment, a top surface of the interconnection insulating layer 110 may be substantially coplanar with the top surfaces of the uppermost ones of the interconnection lines 102. The interconnection insulating layer 110 may be formed of or include at least one of, for example, silicon oxide, silicon nitride, and/or silicon oxynitride.

A first lower insulating layer 120 may be disposed on the interconnection insulating layer 110 to cover the exposed top surfaces of the uppermost ones of the interconnection lines 102. The first lower insulating layer 120 may be disposed on the interconnection insulating layer 110 on the cell region CR and may be extended to the interconnection insulating layer 110 on the boundary and peripheral regions BR and PR. The first lower insulating layer 120 may contact a top surface of the interconnection insulating layer 110 and top surfaces of uppermost ones of the interconnection lines 102. The first lower insulating layer 120 may be formed of or include at least one of, for example, silicon oxide, silicon nitride, and/or silicon oxynitride.

A second lower insulating layer 130 may be disposed on the first lower insulating layer 120. The second lower insulating layer 130 may be disposed on the first lower insulating layer 120 on the cell region CR and may be extended to the first lower insulating layer 120 on the boundary and peripheral regions BR and PR. The second lower insulating layer 130 may contact a top surface of the first lower insulating layer 120. The first lower insulating layer 120 may be interposed between the interconnection insulating layer 110 and the second lower insulating layer 130, on the cell region CR, the boundary region BR, and the peripheral region PR. The second lower insulating layer 130 may be formed of or include at least one of, for example, silicon oxide, silicon nitride, and/or silicon oxynitride.

The second lower insulating layer 130 may include a material different from the first lower insulating layer 120. In an embodiment, the first lower insulating layer 120 may include silicon nitride (e.g., SiCN), and the second lower insulating layer 130 may include silicon oxide (e.g., tetraethyl orthosilicate (TEOS)).

Data storage patterns DS may be disposed on the second lower insulating layer 130 on the cell region CR. The data storage patterns DS may be spaced apart from each other in a horizontal direction. The horizontal direction may be one of the first and second directions D1 and D2. In example embodiments, the data storage patterns DS may be spaced apart from each other in both horizontal directions (e.g., the first and second directions D1 and D2).

The second lower insulating layer 130 on the cell region CR may have a recessed top surface 130RU, which is recessed toward the substrate 100 between the data storage patterns DS. The recessed top surface 130RU of the second lower insulating layer 130 on the cell region CR may be located at a height lower than the uppermost surface 130U1 of the second lower insulating layer 130 on the cell region CR. In the present specification, the height may mean a distance measured from the top surface 100U of the substrate 100 in the vertical direction D3.

A top surface 130U2 of the second lower insulating layer 130 on the peripheral region PR may be located at a height lower than the uppermost surface 130U1 of the second lower insulating layer 130 on the cell region CR. In an embodiment, the top surface 130U2 of the second lower insulating layer 130 on the peripheral region PR may be located at a height lower than the recessed top surface 130RU of the second lower insulating layer 130 on the cell region CR. In another embodiment, the top surface 130U2 of the second lower insulating layer 130 on the peripheral region PR may be located at the same height as the recessed top surface 130RU of the second lower insulating layer 130 on the cell region CR. In other embodiment, the top surface 130U2 of the second lower insulating layer 130 on the peripheral region PR may be located at a height higher than the recessed top surface 130RU of the second lower insulating layer 130 on the cell region CR.

The second lower insulating layer 130 on the boundary region BR may have a recessed top surface 130RUa that is recessed toward the substrate 100. The recessed top surface 130RUa of the second lower insulating layer 130 on the boundary region BR may be located at a height lower than the uppermost surface 130U1 of the second lower insulating layer 130 on the cell region CR. In an embodiment, the recessed top surface 130RUa of the second lower insulating layer 130 on the boundary region BR may be located at a height that is lower than the recessed top surface 130RU of the second lower insulating layer 130 on the cell region CR and is lower than the top surface 130U2 of the second lower insulating layer 130 on the peripheral region PR.

Bottom electrode contacts 140 may be disposed in the second lower insulating layer 130 on the cell region CR and may be spaced apart from each other in the first and second directions D1 and D2. The bottom electrode contacts 140 may be disposed below and electrically connected to the data storage patterns DS, respectively. Each of the bottom electrode contacts 140 may penetrate the first and second lower insulating layers 120 and 130 on the cell region CR and may be connected to the uppermost one of the interconnection lines 102. For example, the first and second lower insulating layers 120 and 130 may contact side surfaces of the bottom electrode contacts 140. In some embodiments, bottom surfaces of the bottom electrode contacts 140 may be coplanar with a bottom surface of the first lower insulating layer 120. Each of the data storage patterns DS may be electrically connected to a corresponding one (e.g., a drain terminal) of terminals of the selection element through a corresponding one of the bottom electrode contacts 140 and the uppermost one of the interconnection lines 102. For example, each of the bottom electrode contacts 140 may contact a lower surface of a corresponding one of the data storage patterns DS and a top surface of a corresponding one of the uppermost one of the interconnection lines 102.

Top surfaces 140U of the bottom electrode contacts 140 may be located at a height higher than the recessed top surface 130RU of the second lower insulating layer 130 on the cell region CR. The top surfaces 140U of the bottom electrode contacts 140 may be located at the same height as the uppermost surface 130U1 of the second lower insulating layer 130 on the cell region CR. The recessed top surface 130RUa of the second lower insulating layer 130 on the boundary region BR and the top surface 130U2 of the second lower insulating layer 130 on the peripheral region PR may be located at a height lower than the top surfaces 140U of the bottom electrode contacts 140.

The bottom electrode contacts 140 may be formed of or include at least one of doped semiconductor materials (e.g., doped silicon), metallic materials (e.g., tungsten, titanium, and/or tantalum), metal-semiconductor compounds (e.g., metal silicide), or conductive metal nitride materials (e.g., titanium nitride, tantalum nitride, and/or tungsten nitride).

Each of the data storage patterns DS may include a bottom electrode BE, the magnetic tunnel junction pattern MTJ, and a top electrode TE, which are sequentially stacked on the second lower insulating layer 130 in the vertical direction D3. The magnetic tunnel junction pattern MTJ may be disposed between the bottom electrode BE and the top electrode TE. For example, the magnetic tunnel junction pattern MTJ may contact a top surface of the bottom electrode BE and a lower surface of the top electrode TE. Each of the bottom electrode contacts 140 may be connected to the bottom electrode BE of each of the data storage patterns DS. The bottom electrode BE of each of the data storage patterns DS may be in contact with the top surface 140U of each of the bottom electrode contacts 140 and the uppermost surface 130U1 of the second lower insulating layer 130 on the cell region CR.

The magnetic tunnel junction pattern MTJ may include a first magnetic pattern MP1, a second magnetic pattern MP2, and the tunnel barrier pattern TBP therebetween. The first magnetic pattern MP1 may be disposed between the bottom electrode BE and the tunnel barrier pattern TBP, and the second magnetic pattern MP2 may be disposed between the top electrode TE and the tunnel barrier pattern TBP. The tunnel barrier pattern TBP may contact a lower surface of the second magnetic pattern MP2 and a top surface of the first magnetic pattern MP1. The bottom electrode BE may be formed of or include at least one of metallic materials (e.g., Pt, W, Co, Ru, Pd, Ir, and Ag). In an embodiment, the bottom electrode BE may be formed of or include at least one of metallic materials (e.g., tungsten, titanium, and tantalum) and/or conductive metal nitrides (e.g., titanium nitride, tantalum nitride, and tungsten nitride). The top electrode TE may be formed of or include at least one of metallic materials (e.g., Pt, W, Co, Ru, Pd, Ir, and Ag). In an embodiment, the top electrode TE may be formed of or include at least one of metallic materials (e.g., tungsten, titanium, and tantalum) and/or conductive metal nitrides (e.g., titanium nitride, tantalum nitride, and tungsten nitride). In an embodiment, the top electrode TE may be formed of or include tantalum nitride.

Referring to FIGS. 4A and 4B, the first magnetic pattern MP1 may be a reference layer having a magnetization direction MD1 fixed in a specific direction, and the second magnetic pattern MP2 may be a free layer having a magnetization direction MD2, which can be changed to be parallel or antiparallel to the magnetization direction MD1 of the first magnetic pattern MP1. For example, the first magnetic pattern MP1 may have a magnetization direction MD1 fixed in a first specific direction, and the second magnetic pattern MP2 may have a magnetization direction MD2 fixed in the first specific direction or in a second specific direction that is opposite to the first specific direction. FIGS. 4A and 4B illustrate an example in which the second magnetic pattern MP2 is used as the free layer, but the inventive concept is not limited to this example. Unlike that shown in FIGS. 4A and 4B, the first magnetic pattern MP1 may be the free layer, and the second magnetic pattern MP2 may be the reference layer.

Referring to FIG. 4A, the magnetization directions MD1 and MD2 of the first and second magnetic patterns MP1 and MP2 may be perpendicular to an interfacial surface between the tunnel barrier pattern TBP and the second magnetic pattern MP2. In this case, each of the first and second magnetic patterns MP1 and MP2 may be formed of or include at least one of intrinsic or extrinsic perpendicular magnetic materials. The intrinsic perpendicular magnetic material may include a material exhibiting a perpendicular magnetization property, even when there is no external cause. The intrinsic perpendicular magnetic material may include at least one of i) perpendicular magnetic materials (e.g., CoFeTb, CoFeGd, and CoFeDy), ii) perpendicular magnetic materials with L10 structure, iii) CoPt-based materials with hexagonal-close-packed structure, or iv) perpendicular magnetic structures. The perpendicular magnetic materials having L1₀ structure may include at least one of FePt having L1₀ structure, FePd having L1₀ structure, CoPd having L1₀ structure, or CoPt having L1₀ structure. The perpendicular magnetic structures may include magnetic and non-magnetic layers that are alternatingly and repeatedly stacked. For example, the perpendicular magnetic structure may include at least one of (Co/Pt)ₙ, (CoFe/Pt)ₙ, (CoFe/Pd)ₙ, (Co/Pd)ₙ, (Co/Ni)ₙ, (CoNi/Pt)ₙ, (CoCr/Pt)ₙ, or (CoCr/Pd)ₙ, where n is the number of stacked pairs of the layers. The extrinsic perpendicular magnetic material may include a material which exhibits an intrinsic in-plane magnetization property when there is no external cause but exhibits a perpendicular magnetization property by an external cause. As an example, the extrinsic perpendicular magnetic material may have a perpendicular magnetization property, due to a magnetic anisotropy that is caused when the first or second magnetic pattern MP1 or MP2 is in contact with the tunnel barrier pattern TBP. The extrinsic perpendicular magnetic material may be formed of or include, for example, CoFeB.

In an embodiment, referring to FIG. 4B, the magnetization directions MD1 and MD2 of the first and second magnetic patterns MP1 and MP2 may be parallel to the interfacial surface between the tunnel barrier pattern TBP and the second magnetic pattern MP2. In this case, each of the first and second magnetic patterns MP1 and MP2 may be formed of or include a ferromagnetic material. The first magnetic pattern MP1 may further include an antiferromagnetic material fixing a magnetization direction of the ferromagnetic material in the first magnetic pattern MP1.

Each of the first and second magnetic patterns MP1 and MP2 may be formed of or include at least one of Co-containing Heusler alloys. The tunnel barrier pattern TBP may be formed of or include at least one of magnesium oxide, titanium oxide, aluminum oxide, magnesium-zinc oxide, or magnesium-boron oxide.

Referring back to FIGS. 2 and 3, a capping insulating layer 150 may be disposed on the second lower insulating layer 130 on the cell region CR. The capping insulating layer 150 may conformally cover a side surface of each of the data storage patterns DS and the recessed top surface 130RU of the second lower insulating layer 130 on the cell region CR. For example, the capping insulating layer 150 may contact the side surface of each of the data storage patterns DS and the recessed top surface 130RU of the second lower insulating layer 130 on the cell region CR. The capping insulating layer 150 may enclose the side surface of each of the data storage patterns DS, when viewed in a plan view. The capping insulating layer 150 may be extended to the boundary region BR to conformally cover the recessed top surface 130RUa of the second lower insulating layer 130 on the boundary region BR. For example, the capping insulating layer 150 may contact the recessed top surface 130RUa of the second lower insulating layer 130 on the boundary region BR.

The capping insulating layer 150 may conformally cover side surfaces of the bottom electrode BE, the magnetic tunnel junction pattern MTJ, and the top electrode TE. For example, the capping insulating layer 150 may contact the side surfaces of the bottom electrode BE, the magnetic tunnel junction pattern MTJ, and the top electrode TE. The capping insulating layer 150 may be provided to enclose the side surfaces of the bottom electrode BE, the magnetic tunnel junction pattern MTJ, and the top electrode TE, when viewed in a plan view. The capping insulating layer 150 may be formed of or include at least one of nitride materials (e.g., silicon nitride).

A cell insulating layer 160 may be disposed on the second lower insulating layer 130 on the cell region CR to cover the data storage patterns DS. The cell insulating layer 160 may be provided to fill a space between the data storage patterns DS. The cell insulating layer 160 may contact the capping insulating layer 150. The capping insulating layer 150 may be interposed between a side surface of each of the data storage patterns DS and the cell insulating layer 160 and may be extended into a region between the recessed top surface 130RU of the second lower insulating layer 130 on the cell region CR and the cell insulating layer 160. The cell insulating layer 160 may be extended to the second lower insulating layer 130 on the boundary region BR. The capping insulating layer 150 may be extended into a region between the recessed top surface 130RUa of the second lower insulating layer 130 on the boundary region BR and the cell insulating layer 160. The cell insulating layer 160 may be formed of or include at least one of silicon oxide, silicon nitride, and/or silicon oxynitride.

A first upper insulating layer 170 may be disposed on the cell insulating layer 160 on the cell region CR. The first upper insulating layer 170 may contact a top surface of the cell insulating layer 160. The first upper insulating layer 170 may be extended to the cell insulating layer 160 on the boundary region BR. The first upper insulating layer 170 may include a material different from the cell insulating layer 160. In an embodiment, the cell insulating layer 160 may be formed of or include silicon oxide, and the first upper insulating layer 170 may be formed of or include silicon nitride (e.g., SiCN).

Cell conductive lines 190 may be respectively disposed on the data storage patterns DS, which are spaced apart from each other in the first direction D1. The cell conductive lines 190 may be spaced apart from each other in the first direction D1 and may be extended in the second direction D2. Each of the cell conductive lines 190 may be provided to penetrate the first upper insulating layer 170 and an upper portion of the cell insulating layer 160 and may be connected to a corresponding one of the data storage patterns DS. Each of the cell conductive lines 190 may be electrically connected to corresponding ones of the data storage patterns DS, which are spaced apart from each other in the second direction D2. The data storage patterns DS, which are spaced apart from each other in the first direction D1, may be electrically and respectively connected to the cell conductive lines 190, which are spaced apart from each other in the first direction D1. Each of the cell conductive lines 190 may be in contact with a corresponding one of the top electrodes TE of the data storage patterns DS. Each of the cell conductive lines 190 may contact a top surface of the capping insulating layer 150 and side surfaces of the cell insulating layer 160 and the first upper insulating layer 170. Top surfaces 190U of the cell conductive lines 190 may be located at the same height as a top surface of the first upper insulating layer 170 and may be coplanar with the top surface of the first upper insulating layer 170. The cell conductive lines 190 may include a conductive or metallic material (e.g., copper).

Referring to FIG. 5A, each of the cell conductive lines 190 may include a first portion 191 and a second portion 192. A bottom surface 191b of the first portion 191 may be in contact with a corresponding one of the top electrodes TE of the data storage patterns DS. The second portion 192 may be disposed on the first portion 191. The first portion 191 may be disposed in a region overlapped with the data storage pattern DS. The second portion 192 may connect the first portions 191, which are spaced apart from each other in the second direction D2, and may have a line shape extending in the second direction D2. For example, the first portions 191 may be placed between the second portion 192 and the data storage patterns DS. A top surface 192a of the second portion 192 may be the top surface 190U of the cell conductive line 190 and may be coplanar with the top surface of the first upper insulating layer 170.

A width 191W of the first portion 191 in the first direction D1 may decrease as a distance from the top surface 100U of the substrate 100 increases in the vertical direction D3. A width 192W of the second portion 192 in the first direction D1 may increase as a distance from the top surface 100U of the substrate 100 increases in the vertical direction D3. In an embodiment, the widths 191W and 192W of the first and second portions 191 and 192 in the first direction D1 may be continuously changed as a distance from the top surface 100U of the substrate 100 increases in the vertical direction D3. The width 191W of the uppermost portion of the first portion 191 in the first direction D1 may be smaller than the width 192W of the lowermost portion of the second portion 192 in the first direction D1. For example, a minimum width 191W of the uppermost portion of the first portion 191 in the first direction D1 may be smaller than a minimum width 192W of the lowermost portion of the second portion 192 in the first direction D1. That is, a width of the cell conductive line 190 in the first direction D1 may be discontinuously or abruptly changed at a boundary between the first and second portions 191 and 192.

The first portion 191 may have a side surface SW2, which is aligned to a side surface SW1 of the data storage pattern DS. The second portion 192 may have side surfaces SW3, which are opposite to each other in the first direction D1. The side surface SW2 of the first portion 191 may be spaced apart from the side surface SW3 of the second portion 192. The side surface SW3 of the second portion 192 may be placed to be horizontally offset from the side surface SW1 of the data storage pattern DS and the side surface SW2 of the first portion 191. The side surface SW3 of the second portion 192 may be misaligned from the side surface SW1 of the data storage pattern DS and the side surface SW2 of the first portion 191.

The second portion 192 may include a stepwise surface SP connecting the side surface SW1 of the first portion 191 to the side surface SW3 of the second portion 192. The stepwise surface SP may be a portion of a bottom surface of the second portion 192 exposed by the first portion 191. The stepwise surface SP may connect the side surface SW2 of the first portion 191 to the side surface SW3 of the second portion 192, at the boundary between the first and second portions 191 and 192. In an embodiment, the stepwise surface SP may be located at the same height as the boundary between the first and second portions 191 and 192. In example embodiments, the stepwise surface SP may be parallel to the top surface 100U of the substrate 100.

The side surface SW2 of the first portion 191 may be inclined at a first angle 10 to the bottom surface 191b of the first portion 191. The side surface SW3 of the second portion 192 may be inclined at a second angle 20 to the stepwise surface SP. The first angle 10 and the second angle 20 may be different from each other. In an embodiment, the first angle 10 may be an acute angle, and the second angle 20 may be an obtuse angle.

The capping insulating layer 150 may conformally cover the side surface SW1 of the data storage pattern DS and may be extended to the side surface SW2 of the first portion 191. The capping insulating layer 150 may be extended to the stepwise surface SP to be in contact with a portion of a bottom surface of the second portion 192. The uppermost surface 150a of the capping insulating layer 150 may be in contact with the stepwise surface SP. The capping insulating layer 150 may not be extended to the side surface SW3 of the second portion 192. The capping insulating layer 150 may be horizontally overlapped with the data storage pattern DS and the first portion 191 and may not be horizontally overlapped with the second portion 192. The capping insulating layer 150 may conformally cover the side surface SW1 of the data storage pattern DS and the side surface SW2 of the first portion 191. The first portion 191 may be spaced apart from the cell insulating layer 160, with the capping insulating layer 150 interposed therebetween.

The first portion 191 may have a first thickness T1, and the top electrode TE may have a second thickness T2. In the present specification, the thickness may mean a thickness measured in the vertical direction D3. In an embodiment, the second thickness T2 may range from 5 nm to 40 nm. The first thickness T1 may be smaller than 35 nm. For example, the second thickness T2 may range from 5 nm to 1.5 nm, and the first thickness T1 may range from 2.5 nm to 3.5 nm. The sum of the first and second thicknesses T1 and T2 may be about 40 nm. For example, the sum of the first and second thicknesses T1 and T2 may be substantially equal to 40 nm. In the case where the first and second thicknesses T 1 and T2 are within the afore-described thickness range, it may be possible to effectively prevent an effect, which is caused by chemicals and plasma produced in a fabrication process.

FIG. 5B is an enlarged sectional view illustrating a portion ‘P’ of FIG. 3, according to an embodiment different from FIG. 5A. For concise description, an element different from the embodiment of FIG. 5A will be mainly described below.

Referring to FIG. 5B, the cell conductive line 190 may include the first portion 191, the second portion 192, and a conductive barrier pattern 193. The conductive barrier pattern 193 may be provided to enclose the first and second portions 191 and 192. In detail, the conductive barrier pattern 193 may be interposed between the top surface of the data storage pattern DS (e.g., the top surface of the top electrode TE) and the first portion 191 and may be extended to regions between the capping insulating layer 150 and the first and second portions 191 and 192, between the cell insulating layer 160 and the second portion 192, and between the first upper insulating layer 170 and the second portion 192. The uppermost surface of the conductive barrier pattern 193 may be substantially coplanar with the top surface of the first upper insulating layer 170 and the top surface 192a of the second portion 192. The conductive barrier pattern 193 may be formed of or include, for example, a conductive metal nitride.

The conductive barrier pattern 193 may have the first side surface SW2 enclosing the first portion 191 and may have the second side surface SW3 enclosing the second portion 192. That is, the conductive barrier pattern 193 may have the first and second side surfaces SW2 and SW3, which are horizontally overlapped with the first and second portions 191 and 192, respectively. The first side surface SW2 may be aligned to the side surface SW1 of the data storage pattern DS. The second side surface SW3 may be misaligned from the side surface SW1 of the data storage pattern DS and the first side surface SW2.

The capping insulating layer 150 may conformally cover the side surface SW1 of the data storage pattern DS and may be extended to the first side surface SW2 of the conductive barrier pattern 193. The capping insulating layer 150 may be further extended to the second side surface SW3 of the conductive barrier pattern 193. However, the uppermost portion 150u of the capping insulating layer 150 may be located at a height lower than a top surface of the cell insulating layer 160. That is, the capping insulating layer 150 may be overlapped with the entirety of the first portion 191 and a portion of the second portion 192, in a horizontal direction.

The width 191W of the first portion 191 in the first direction D1 may decrease as a distance from the top surface 100U of the substrate 100 increases in the vertical direction D3. The width 192W of the second portion 192 in the first direction D1 may increase as a distance from the top surface 100U of the substrate 100 increases in the vertical direction D3. The width 191W of the uppermost portion of the first portion 191 in the first direction D1 may be substantially equal to the width 192W of the lowermost portion of the second portion 192 in the first direction D1. In other words, the widths 191W and 192W of the first and second portions 191 and 192 in the first direction D1 may be continuously changed at the boundary between the first and second portions 191 and 192.

Referring back to FIGS. 2 and 3, a peripheral insulating layer 180 may be disposed on the second lower insulating layer 130 on the peripheral region PR. The peripheral insulating layer 180 may be in contact with the top surface 130U2 of the second lower insulating layer 130 on the peripheral region PR. The peripheral insulating layer 180 may be in contact with a side surface 160S of the cell insulating layer 160 and may be in contact with a side surface 170S of the first upper insulating layer 170. The peripheral insulating layer 180 may also be in contact with a side surface 150S of the capping insulating layer 150.

A top surface 180U of the peripheral insulating layer 180 may be located at the same height as the top surface of the first upper insulating layer 170. The top surface 180U of the peripheral insulating layer 180 may be coplanar with the top surface of the first upper insulating layer 170.

The peripheral insulating layer 180 may be formed of or include at least one of, for example, silicon oxide, silicon nitride, and/or silicon oxynitride. The peripheral insulating layer 180 may include a material different from the cell insulating layer 160.

Peripheral conductive lines 210 may be disposed in the peripheral insulating layer 180 and on the second lower insulating layer 130 on the peripheral region PR. The peripheral insulating layer 180 may cover the peripheral conductive lines 210. Top surfaces 210U of the peripheral conductive lines 210 may not be covered with the peripheral insulating layer 180 and may be exposed to the outside of the peripheral insulating layer 180. The top surfaces 210U of the peripheral conductive lines 210 may be located at the same height as the top surface 180U of the peripheral insulating layer 180 and may be coplanar with the top surface 180U of the peripheral insulating layer 180. The top surfaces 210U of the peripheral conductive lines 210, the top surface 180U of the peripheral insulating layer 180, the top surfaces 190U of the cell conductive lines 190, and the top surface of the first upper insulating layer 170 may be located at the same height and may be coplanar with each other.

Peripheral conductive contacts 220 may be disposed on the peripheral region PR and below the peripheral conductive lines 210. The peripheral conductive contacts 220 may be electrically connected to the peripheral conductive lines 210. Each of the peripheral conductive contacts 220 may be in contact with a corresponding one of the peripheral conductive lines 210 without an interfacial surface. Each of the peripheral conductive contacts 220 and the corresponding peripheral conductive line 210 may be connected to each other to form a single object. The peripheral conductive contacts 220 and the corresponding peripheral conductive line 210 may form a single homogeneous monolithic structure. Each of the peripheral conductive contacts 220 may be provided to penetrate a lower portion of the peripheral insulating layer 180. Each of the peripheral conductive contacts 220 may be provided to penetrate the second and first lower insulating layers 130 and 120 on the peripheral region PR and may be electrically connected to a corresponding one of the uppermost ones of the interconnection lines 102. The peripheral insulating layer 180 and the first and second lower insulating layers 120 and 130 may contact side surfaces of the peripheral conductive lines 210. Each of the peripheral conductive lines 210 may be electrically connected to a corresponding one of terminals (e.g., source, drain, and gate terminals) of the peripheral transistors through a corresponding one of the peripheral conductive contacts 220 and the uppermost one of the interconnection lines 102.

The peripheral conductive lines 210 and the peripheral conductive contacts 220 may include a conductive or metallic material (e.g., copper). The cell conductive lines 190, the peripheral conductive lines 210, and the peripheral conductive contacts 220 may be formed of or include the same material.

An upper interlayer insulating layer 200 may be disposed on the cell region CR, the boundary region BR, and the peripheral region PR to cover the top surface of the first upper insulating layer 170, the top surfaces 190U of the cell conductive lines 190, the top surface 180U of the peripheral insulating layer 180, and the top surfaces 210U of the peripheral conductive lines 210. The upper interlayer insulating layer 200 may contact the top surface of the first upper insulating layer 170, the top surfaces 190U of the cell conductive lines 190, the top surface 180U of the peripheral insulating layer 180, and the top surfaces 210U of the peripheral conductive lines 210. Top surfaces of the upper interlayer insulating layer 200 and the bit lines BL may be coplanar. The upper interlayer insulating layer 200 may be formed of or include at least one of, for example, silicon oxide, silicon nitride, and/or silicon oxynitride.

The bit lines BL may be disposed in the upper interlayer insulating layer 200 on the cell region CR. The bit lines BL may be spaced apart from each other in the first direction D1 and may be extended in the second direction D2. Conductive vias 194 may be disposed in the upper interlayer insulating layer 200 on the cell region CR and may be disposed between the cell conductive lines 190 and the bit lines BL. The conductive vias 194 may contact top surfaces of the cell conductive lines 190 and bottom surfaces of the bit lines BL, and the upper interlayer insulating layer 200 may contact side surfaces of the cell conductive lines 190 and the bit lines BL. The cell conductive lines 190 may be electrically connected to the bit lines BL through the conductive vias 194. Each of the cell conductive lines 190 may be electrically connected to a corresponding one of the bit lines BL through a corresponding one of the conductive vias 194 and the cell conductive line 190 and the bit line BL, which are connected to each other, may serve as the bit line BL of FIG. 1. The conductive vias 194 and the bit lines BL may include a conductive or metallic material (e.g., copper).

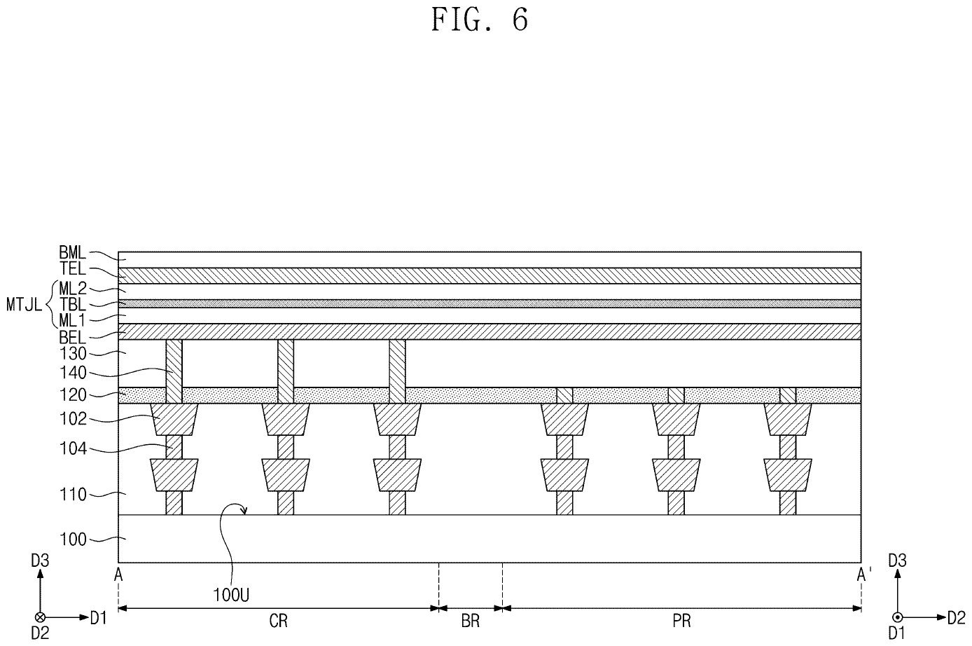

FIGS. 6 to 15 are sectional views, which are taken along a line A-A′ of FIG. 2 to illustrate a method of fabricating a semiconductor device according to an example embodiment of the inventive concept. For concise description, an element previously described with reference to FIGS. FIGS. 1 to 3, 4A, 4B, and 5 may be identified by the same reference number without repeating an overlapping description thereof.

Referring to FIGS. 2 and 6, the substrate 100 including the cell region CR, the peripheral region PR, and the boundary region BR therebetween may be provided. The selection elements SE of FIG. 1 and the peripheral transistors may be formed on the substrate 100, and the interconnection structures 102 and 104 may be formed on the selection elements SE and the peripheral transistors. The interconnection structures 102 and 104 may include the interconnection lines 102, which are spaced apart from the substrate 100 vertically (e.g., in the third direction D3), and the interconnection contacts 104, which are connected to the interconnection lines 102. Each of the interconnection lines 102 may be electrically connected to a corresponding one of terminals (e.g., source, drain, and gate terminals) of the selection elements or peripheral transistors through a corresponding one of the interconnection contacts 104.

The interconnection insulating layer 110 may be formed on the substrate 100 to cover the interconnection structures 102 and 104. The interconnection insulating layer 110 may be formed to expose top surfaces of the uppermost ones of the interconnection lines 102.

The first lower insulating layer 120 may be formed on the interconnection insulating layer 110 to cover the exposed top surfaces of the uppermost ones of the interconnection lines 102. The first lower insulating layer 120 may be formed on the interconnection insulating layer 110 on the cell region CR and may be extended to the interconnection insulating layer 110 on the boundary and peripheral regions BR and PR.

The second lower insulating layer 130 may be formed on the first lower insulating layer 120. The second lower insulating layer 130 may be formed on the first lower insulating layer 120 on the cell region CR and may be extended to the first lower insulating layer 120 on the boundary and peripheral regions BR and PR.

The bottom electrode contacts 140 may be formed in the second lower insulating layer 130 on the cell region CR. Each of the bottom electrode contacts 140 may be provided to penetrate the first and second lower insulating layers 120 and 130 on the cell region CR and may be electrically connected to one of the uppermost ones of the interconnection lines 102. In an embodiment, the formation of the bottom electrode contacts 140 may include forming lower contact holes on the cell region CR to penetrate the first and second lower insulating layers 120 and 130, forming a lower contact layer on the second lower insulating layer 130 to fill the lower contact holes, and planarizing the lower contact layer to expose a top surface of the second lower insulating layer 130. The bottom electrode contacts 140 may be locally formed in the lower contact holes, respectively, by the planarization process.

A bottom electrode layer BEL, a magnetic tunnel junction layer MTJL, a top electrode layer TEL, and a blocking mask layer BML may be sequentially formed on the second lower insulating layer 130. The bottom electrode layer BEL, the magnetic tunnel junction layer MTJL, the top electrode layer TEL, and the blocking mask layer BML may be formed on the second lower insulating layer 130 on the cell region CR and may be extended to the second lower insulating layer 130 on the boundary and peripheral regions BR and PR. The magnetic tunnel junction layer MTJL may include a first magnetic layer ML1, a tunnel barrier layer TBL, and a second magnetic layer ML2, which are sequentially stacked on the bottom electrode layer BEL. The top electrode layer TEL may include at least one of metallic materials (e.g., Pt, W, Co, Ru, Pd, Ir, and Ag). In an embodiment, the top electrode layer TEL may be formed of or include at least one of metallic materials (e.g., tungsten, titanium, and tantalum) and/or conductive metal nitrides (e.g., titanium nitride, tantalum nitride, and tungsten nitride). For example, the top electrode layer TEL may be formed of or include tantalum nitride. The blocking mask layer BML may be formed of or include, for example, silicon nitride and/or metal nitride. The bottom electrode layer BEL, the magnetic tunnel junction layer MTJL, the top electrode layer TEL, and the blocking mask layer BML may be formed using a layer-forming method (e.g., a chemical vapor deposition (CVD) method, a physical vapor deposition (PVD) method, and an atomic layer deposition (ALD) method).

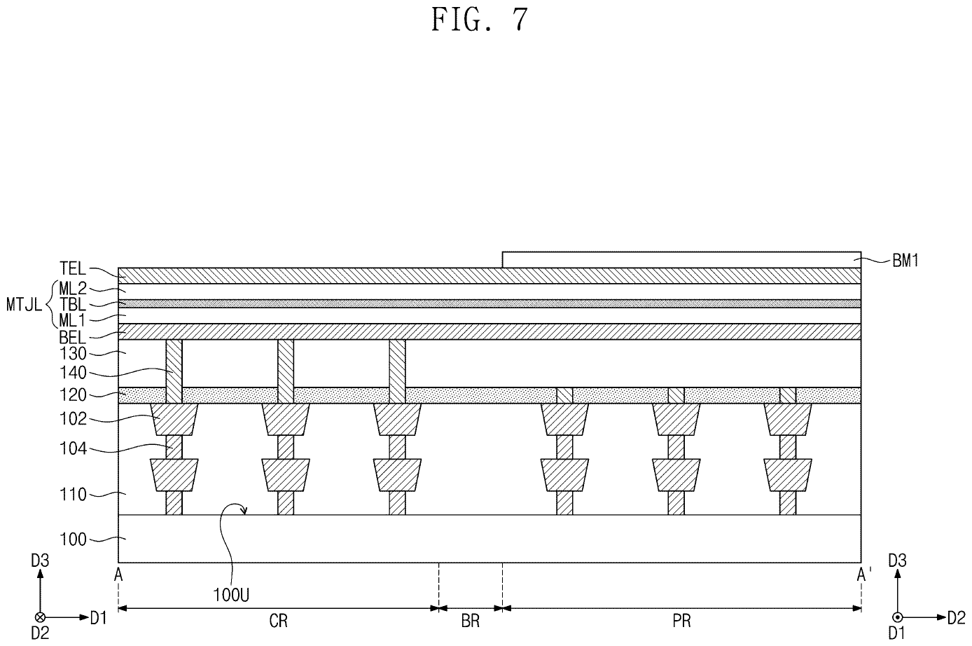

Referring to FIGS. 2 and 7, a first blocking mask pattern BM1 may be formed on the top electrode layer TEL on the peripheral region PR. The first blocking mask pattern BM1 may be formed to cover the top electrode layer TEL on the peripheral region PR and to expose the top electrode layer TEL on the boundary region BR and the cell region CR. In an embodiment, the formation of the first blocking mask pattern BM1 may include forming a mask pattern (not shown) on the blocking mask layer BML to expose the boundary region BR and the cell region CR and etching the exposed blocking mask layer BML using the mask pattern as etch mask.

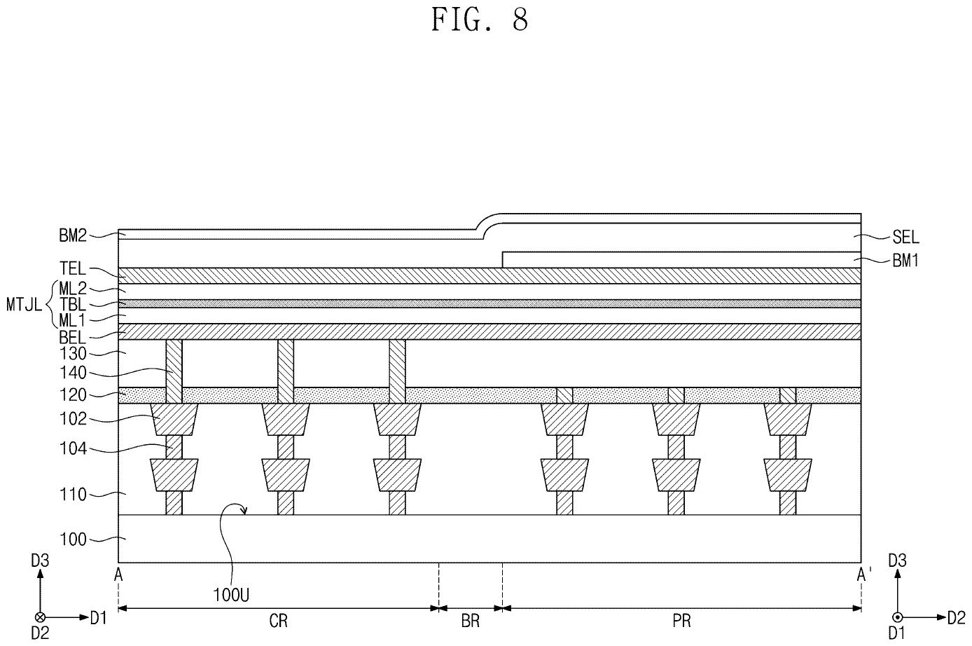

Referring to FIGS. 2 and 8, a sacrificial electrode layer SEL and a second blocking mask pattern BM2 may be sequentially formed on the top electrode layer TEL and the first blocking mask pattern BM1. In detail, the sacrificial electrode layer SEL may be formed on the top electrode layer TEL on the cell and boundary regions CR and BR and may be extended to the first blocking mask pattern BM1 on the peripheral region PR. The second blocking mask pattern BM2 may be formed on the sacrificial electrode layer SEL. The sacrificial electrode layer SEL may include, for example, a conductive metal nitride. In an embodiment, the sacrificial electrode layer SEL may be formed of or include titanium nitride. The sacrificial electrode layer SEL and the second blocking mask pattern BM2 may be formed using a layer-forming method (e.g., a chemical vapor deposition (CVD) method, a physical vapor deposition (PVD) method, and an atomic layer deposition (ALD) method).

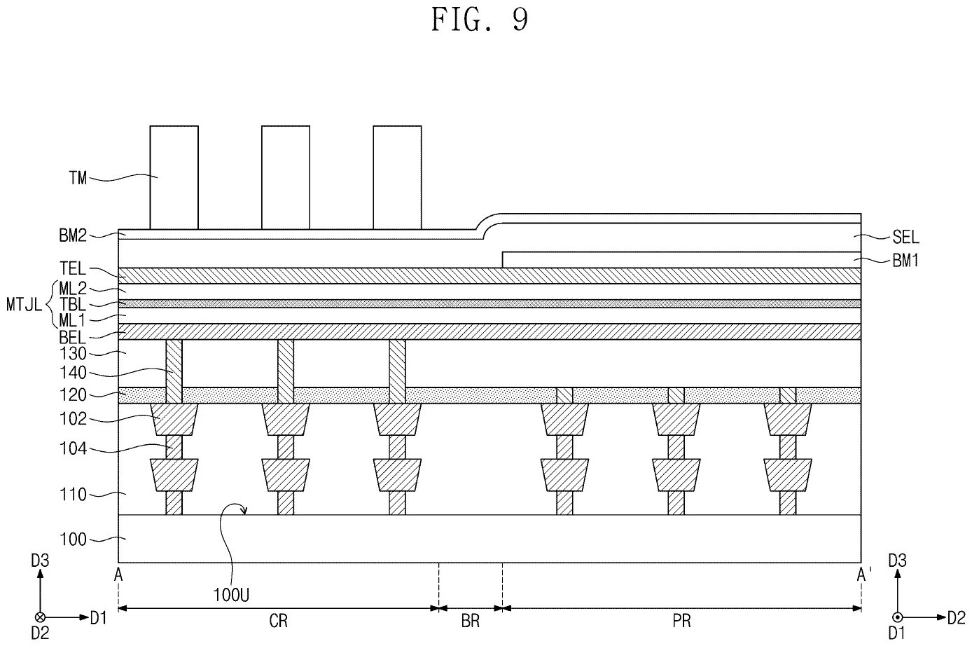

Referring to FIGS. 2 and 9, mask patterns TM may be formed on the second blocking mask pattern BM2 on the cell region CR. The mask patterns TM may define regions where magnetic tunnel junction patterns MTJ to be described below will be formed. The mask patterns TM may be spaced apart from each other in the first and second directions D1 and D2, on the second blocking mask pattern BM2.

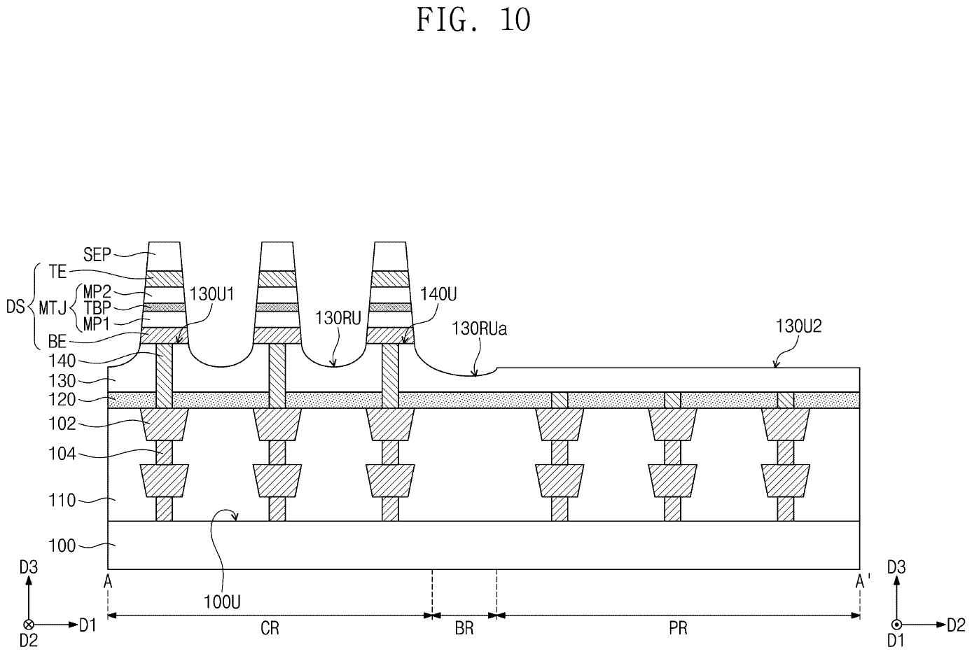

Referring to FIGS. 2 and 10, a first etching process using the mask patterns TM as an etch mask may be performed to etch the second blocking mask pattern BM2, the sacrificial electrode layer SEL, the top electrode layer TEL, the magnetic tunnel junction layer MTJL and the bottom electrode layer BEL. The first etching process may be, for example, an ion beam etching process using an ion beam. The ion beam may include inert ions. The mask patterns TM, the second blocking mask pattern BM2, and the first blocking mask pattern BM1 may be removed by the first etching process. A sacrificial electrode SEP may be formed as a result of the etching of the sacrificial electrode layer SEL. The top electrode TE may be formed as a result of the etching of the top electrode layer TEL. The magnetic tunnel junction pattern MTJ and the bottom electrode BE may be respectively formed as a result of the etching of the magnetic tunnel junction layer MTJL and the bottom electrode layer BEL.

The etching of the magnetic tunnel junction layer MTJL may include sequentially etching the second magnetic layer ML2, the tunnel barrier layer TBL, and the first magnetic layer ML1. The second magnetic layer ML2, the tunnel barrier layer TBL, and the first magnetic layer ML1 may be etched to form the second magnetic pattern MP2, the tunnel barrier pattern TBP, and the first magnetic pattern MP1, respectively. After the first etching process, a remaining portion of the top electrode layer TEL, which is left on the magnetic tunnel junction pattern MTJ, may be referred to as the top electrode TE. After the first etching process, a remaining portion of the sacrificial electrode layer SEL, which is left on the top electrode TE, may be referred to as the sacrificial electrode SEP. The bottom electrode BE, the magnetic tunnel junction pattern MTJ, and the top electrode TE may be referred to as the data storage pattern DS. The data storage patterns DS may be formed on the bottom electrode contacts 140, respectively, and may be spaced apart from each other in the first and second directions D1 and D2.

An upper portion of the second lower insulating layer 130 between the data storage patterns DS may be recessed by the first etching process. Thus, the second lower insulating layer 130 on the cell region CR may have the recessed top surface 130RU that is recessed toward the substrate 100. The recessed top surface 130RU of the second lower insulating layer 130 on the cell region CR may be located at a height that is lower than the top surfaces 140U of the bottom electrode contacts 140 and is lower than the uppermost surface 130U1 of the second lower insulating layer 130 on the cell region CR.

The first and second blocking mask patterns BM1 and BM2 may be removed during the first etching process, and the sacrificial electrode layer SEL, the top electrode layer TEL, the magnetic tunnel junction layer MTJL, and the bottom electrode layer BEL on the boundary and peripheral regions BR and PR may also be removed during the first etching process. In addition, an upper portion of the second lower insulating layer 130 on the boundary and peripheral regions BR and PR may be recessed by the first etching process.

The top surface 130U2 of the second lower insulating layer 130 on the peripheral region PR may be located at a height lower than the uppermost surface 130U1 of the second lower insulating layer 130 on the cell region CR. The recessed top surface 130RUa of the second lower insulating layer 130 on the boundary region BR may be located at a height lower than the uppermost surface 130U1 of the second lower insulating layer 130 on the cell region CR.

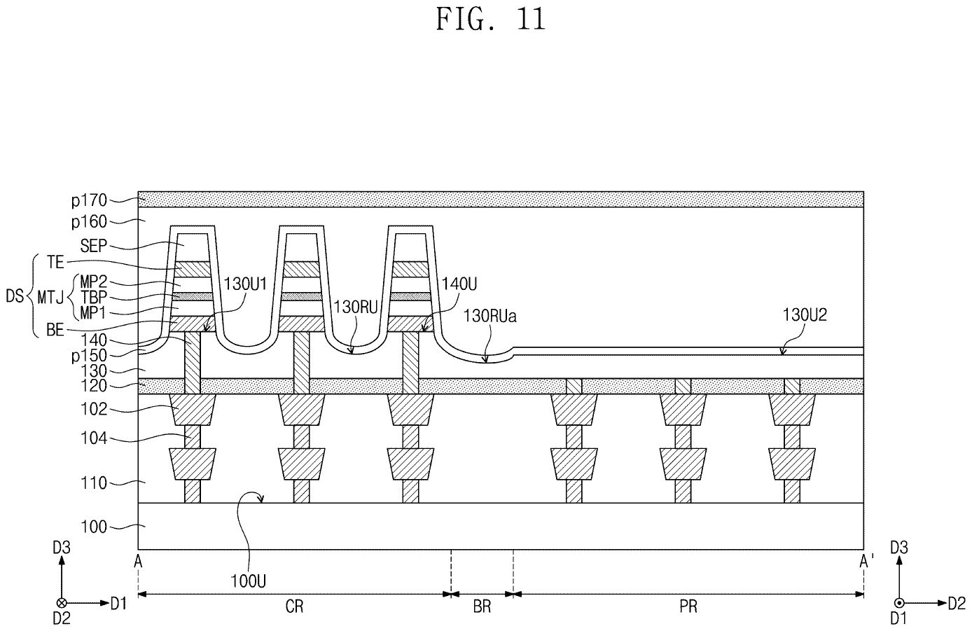

Referring to FIGS. 2 and 11, a preliminary capping insulating layer p150 may be formed on the second lower insulating layer 130 on the cell region CR to conformally cover a side surface of each of the data storage patterns DS and side and top surfaces of the sacrificial electrode SEP. The preliminary capping insulating layer p150 may conformally cover the recessed top surface 130RU of the second lower insulating layer 130 on the cell region CR. The preliminary capping insulating layer p150 may be extended to the boundary region BR to conformally cover the recessed top surface 130RUa of the second lower insulating layer 130 on the boundary region BR. The preliminary capping insulating layer p150 may be extended to the peripheral region PR to cover the top surface 130U2 of the second lower insulating layer 130 on the peripheral region PR.

A preliminary cell insulating layer p160 may be formed on the preliminary capping insulating layer p150. The preliminary cell insulating layer p160 may be formed on the preliminary capping insulating layer p150 on the cell region CR to cover the data storage patterns DS and the sacrificial electrodes SEP and to fill a space between the data storage patterns DS and the sacrificial electrodes SEP. The preliminary cell insulating layer p160 may be extended to the preliminary capping insulating layer p150 on the boundary and peripheral regions BR and PR. The preliminary cell insulating layer p160 may be formed using, for example, a high density plasma chemical vapor deposition (HDP CVD) process.

A preliminary upper insulating layer p170 may be formed on the preliminary cell insulating layer p160. The preliminary upper insulating layer p170 may be formed on the preliminary cell insulating layer p160 on the cell region CR and may be extended to the preliminary cell insulating layer p160 on the boundary and peripheral regions BR and PR.

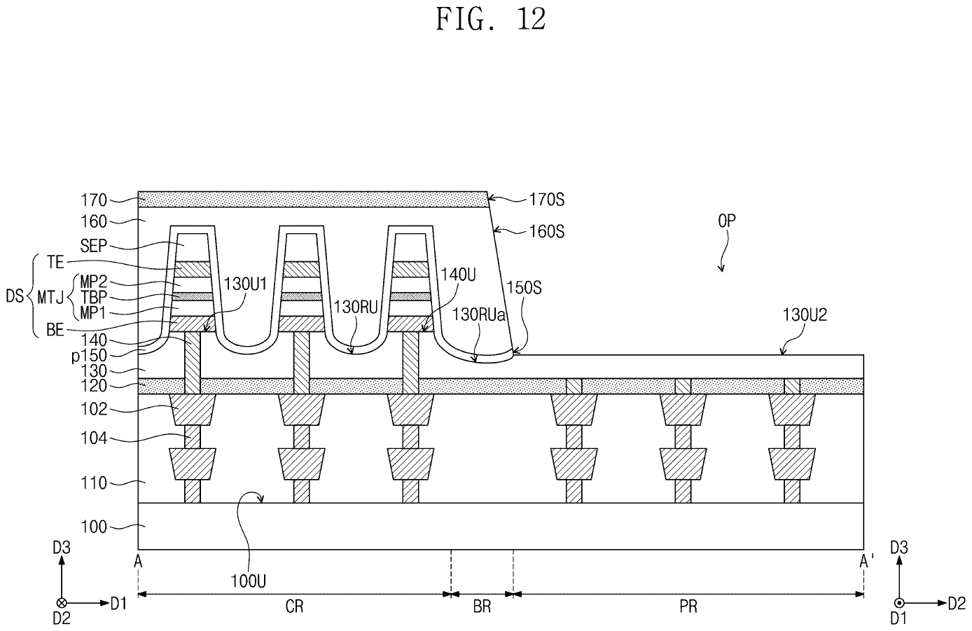

Referring to FIGS. 2 and 12, a peripheral opening OP may be formed on the peripheral region PR to expose the top surface 130U2 of the second lower insulating layer 130 on the peripheral region PR. The peripheral opening OP may be formed on the boundary region BR to expose the side surface 170S of the first upper insulating layer 170, the side surface 160S of the cell insulating layer 160, and the side surface 150S of the preliminary capping insulating layer p150.

The formation of the peripheral opening OP may include performing a second etching process to remove the preliminary upper insulating layer p170, the preliminary cell insulating layer p160, and the preliminary capping insulating layer p150 on the peripheral region PR. In an embodiment, the formation of the peripheral opening OP may include forming a cell mask pattern on the cell region CR to cover the preliminary upper insulating layer p170 and performing the second etching process using the cell mask pattern as an etch mask. The cell mask pattern may be, for example, a photoresist pattern. Since the preliminary upper insulating layer p170 and the preliminary cell insulating layer p160 on the peripheral region PR are removed by the second etching process, the first upper insulating layer 170 and the cell insulating layer 160 may be formed. The preliminary capping insulating layer p150 may be left on only the cell and boundary regions CR and BR by the second etching process. As a result of the second etching process, the top surface 130U2 of the second lower insulating layer 130 on the peripheral region PR may be exposed to the outside, and the side surface 170S of the first upper insulating layer 170, the side surface 160S of the cell insulating layer 160, and the side surface 150S of the preliminary capping insulating layer p150 on the boundary region BR may be exposed to the outside.

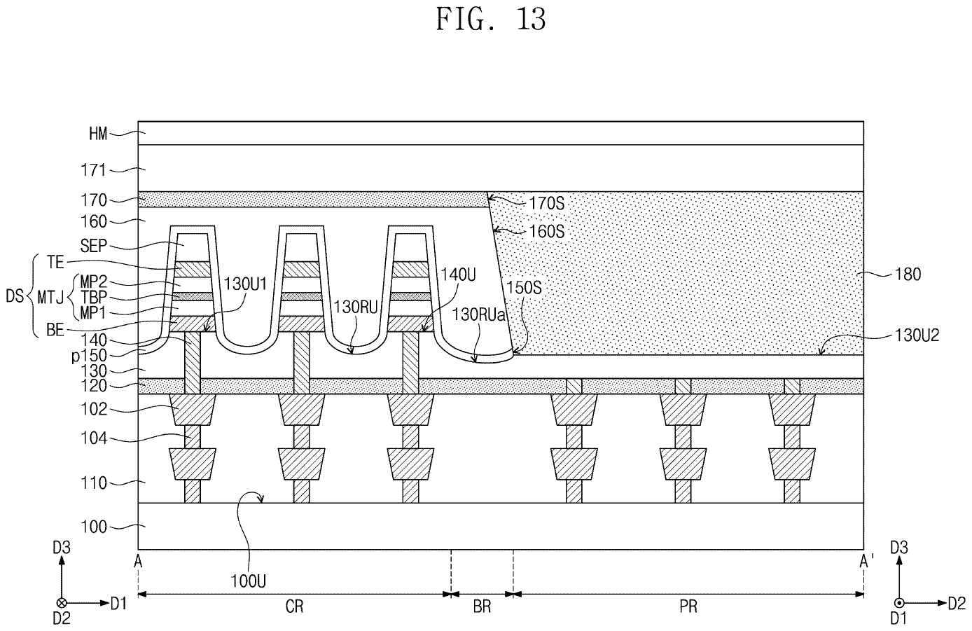

Referring to FIGS. 2 and 13, the peripheral insulating layer 180 may be formed to fill the peripheral opening OP. The peripheral insulating layer 180 may be in contact with the top surface 130U2 of the second lower insulating layer 130 on the peripheral region PR and may be in contact with the side surface 150S of the preliminary capping insulating layer p150, the side surface 160S of the cell insulating layer 160, and the side surface 170S of the first upper insulating layer 170 on the boundary region BR. In an embodiment, the formation of the peripheral insulating layer 180 may include forming an insulating layer to fill the peripheral opening OP and planarizing the insulating layer to expose the top surface of the first upper insulating layer 170. The insulating layer may be formed using, for example, a chemical vapor deposition process. The planarization process may be performed using at least one of, for example, an etch-back process and a chemical mechanical polishing (CMP) process.

A second upper insulating layer 171 and a hard mask layer HM may be sequentially formed on the first upper insulating layer 170 and the peripheral insulating layer 180. The second upper insulating layer 171 and the hard mask layer HM may be formed using a layer-forming method (e.g., a chemical vapor deposition (CVD) method or a physical vapor deposition (PVD) method). The hard mask layer HM may be formed of or include, for example, a conductive metal nitride. In an embodiment, the hard mask layer HM may include the same material as the sacrificial electrode SEP. In an embodiment, the hard mask layer HM may be formed of or include titanium nitride.

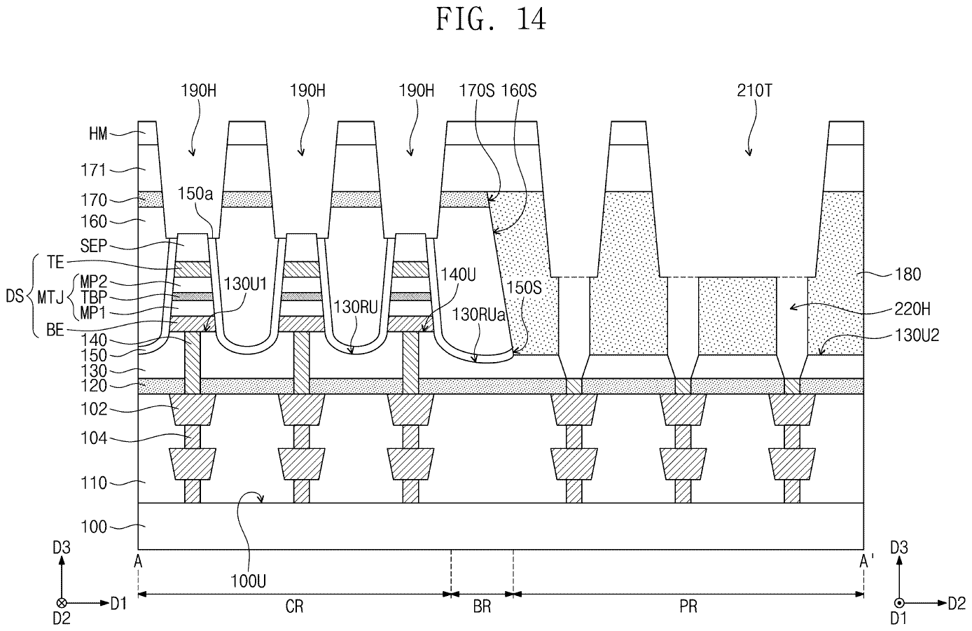

Referring to FIGS. 2 and 14, first cell trenches 190H may be formed on the cell region CR. Each of the first cell trenches 190H may be formed to expose a corresponding one of the sacrificial electrodes SEP. Each of the first cell trenches 190H may be formed to penetrate the hard mask layer HM, the second upper insulating layer 171, the first upper insulating layer 170, and an upper portion of the cell insulating layer 160. In addition, an upper portion of the preliminary capping insulating layer p150 may be etched during the formation of the first cell trenches 190H. Thus, the capping insulating layer 150 may be formed.

The uppermost surface 150a of the capping insulating layer 150 may be located at a height lower than top surfaces of the sacrificial electrodes SEP. The uppermost surface 150a of the capping insulating layer 150 may be located at a height higher than top surfaces of the data storage patterns DS. The capping insulating layer 150 may cover a portion of the side surface of the sacrificial electrode SEP. An upper portion of each of the sacrificial electrodes SEP may protrude from the uppermost surface 150a of the capping insulating layer 150.

Peripheral trenches 210T may be formed in the peripheral insulating layer 180 on the peripheral region PR. Each of the peripheral trenches 210T may be formed to penetrate the hard mask layer HM, the second upper insulating layer 171, and an upper portion of the peripheral insulating layer 180. Peripheral holes 220H may be formed to extend from bottom surfaces of the peripheral trenches 210T toward the substrate 100. Each of the peripheral holes 220H may penetrate a lower portion of the peripheral insulating layer 180 and may penetrate the second and first lower insulating layers 130 and 120 on the peripheral region PR. Each of the peripheral holes 220H may be formed to expose a top surface of the uppermost one of the interconnection lines 102.

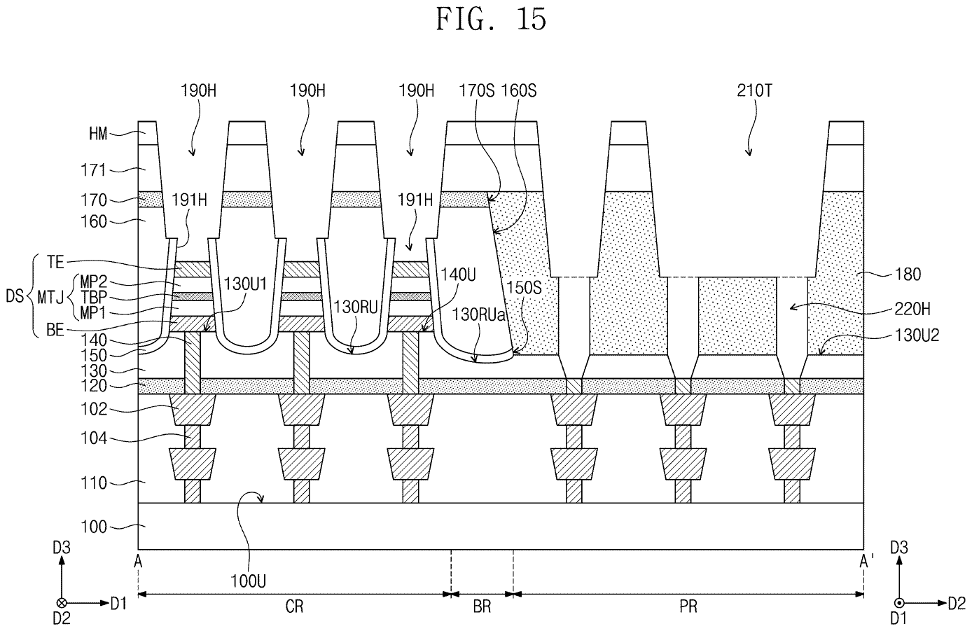

Referring to FIGS. 2 and 15, first holes 191H may be formed on the data storage patterns DS, respectively. The first holes 191H may have a shape extending from the first cell trenches 190H toward the substrate 100. The first holes 191H may be formed by removing the sacrificial electrodes SEP. In an embodiment, the sacrificial electrodes SEP may be removed through a third etching process. The third etching process may include, for example, a wet etching process. The hard mask layer HM may also be removed during the third etching process. This is because the sacrificial electrode SEP and the hard mask layer HM are formed of or include the same material.

Referring back to FIGS. 2 and 3, the cell conductive lines 190 may be formed in the first cell trenches 190H and the first holes 191H. The peripheral conductive lines 210 may be formed in the peripheral trenches 210T, respectively, and the peripheral conductive contacts 220 may be formed in the peripheral holes 220H, respectively. The formation of the cell conductive lines 190, the peripheral conductive lines 210, and the peripheral conductive contacts 220 may include forming a conductive layer to fill the first cell trenches 190H, the first holes 191H, the peripheral trenches 210T, and the peripheral holes 220H and planarizing the conductive layer to expose the top surface of the first upper insulating layer 170 and the top surface 180U of the peripheral insulating layer 180. The second upper insulating layer 171 may be removed by the planarization process. As a result of the planarization process, the top surfaces 190U of the cell conductive lines 190, the top surface of the first upper insulating layer 170, the top surface 180U of the peripheral insulating layer 180, and the top surfaces 210U of the peripheral conductive lines 210 may be placed at the same height.

According to an embodiment of the inventive concept, the sacrificial electrode SEP may be disposed on the top electrode TE, before the forming of the cell conductive line 190. The sacrificial electrode SEP may include the same material as the hard mask layer HM. Before the forming of the cell conductive line 190, the sacrificial electrode SEP and the hard mask layer HM may be removed by the third etching process. In the case where the sacrificial electrode SEP is absent as in the conventional technology, the hard mask layer HM may be removed by a planarization process, which is performed after forming a conductive layer for the cell conductive line 190. However, the hard mask layer HM may not be fully removed by the planarization process. For example, a portion of the hard mask layer HM may be left, and in this case, a bridge issue may occur. According to an embodiment of the inventive concept, the hard mask layer HM may be removed by the third etching process including the wet etching process, and in this case, it may be possible to fully remove a residue of the hard mask layer HM in the first cell trench 190H. In addition, the data storage pattern DS may be protected by the sacrificial electrode SEP, during the third etching process. Thus, it may be possible to form the cell conductive line 190 without a void. In addition, since the top electrode TE is left after the removing of the sacrificial electrode SEP, it may be possible to prevent an effect caused by plasma in a subsequent process. Accordingly, a semiconductor device with improved electrical and reliability characteristics and a method of fabricating the same may be provided.

Referring back to FIGS. 2 and 3, the upper interlayer insulating layer 200 may be formed on the cell region CR, the boundary region BR, and the peripheral region PR to cover the top surface of the first upper insulating layer 170, the top surfaces 190U of the cell conductive lines 190, the top surface 180U of the peripheral insulating layer 180, and the top surfaces 210U of the peripheral conductive lines 210.

The bit lines BL and the conductive vias 194 may be formed in the upper interlayer insulating layer 200. In an embodiment, the formation of the bit lines BL and the conductive vias 194 may include forming second cell trenches to penetrate an upper portion of the upper interlayer insulating layer 200, forming contact holes to penetrate a lower portion of the upper interlayer insulating layer 200 from a bottom surface of each of the second cell trenches, forming a conductive layer on the upper interlayer insulating layer 200 to fill the second cell trenches and the contact holes, and planarizing the conductive layer to expose a top surface of the upper interlayer insulating layer 200.

According to an embodiment of the inventive concept, a hard mask layer may be removed by a wet etching process, before forming cell conductive lines, and a residue of the hard mask layer may be fully removed. Thus, it may be possible to form the cell conductive lines without a void. In addition, since a top electrode is left after the removal of the hard mask layer, it may be possible to prevent a technical issue caused by plasma in a subsequent process.

Thus, it may be possible to reduce a defect in a fabrication process and to improve electrical and reliability characteristics of a semiconductor device.

While example embodiments of the inventive concept have been particularly shown and described, it will be understood by one of ordinary skill in the art that variations in form and detail may be made therein without departing from the spirit and scope of the attached claims.

1. A semiconductor device, comprising:
a lower insulating layer on a substrate;
a data storage pattern on the lower insulating layer;
a cell insulating layer on the lower insulating layer to cover the data storage pattern;
a cell conductive line on the data storage pattern; and
a capping insulating layer interposed between a side surface of the data storage pattern and the cell insulating layer,
wherein the cell conductive line comprises a first portion adjacent to the data storage pattern and a second portion on the first portion, and
wherein the capping insulating layer is extended to a side surface of the first portion.

2. The semiconductor device of claim 1, wherein the side surface of the first portion is spaced apart from a side surface of the second portion in a first direction that is parallel to a top surface of the substrate.

3. The semiconductor device of claim 2, wherein the cell conductive line comprises a stepwise surface connecting the side surface of the first portion to the side surface of the second portion.

4. The semiconductor device of claim 3, wherein the uppermost surface of the capping insulating layer is in contact with the stepwise surface.

5. The semiconductor device of claim 3,
wherein the side surface of the first portion is inclined at a first angle to a bottom surface of the first portion,
wherein the side surface of the second portion is inclined at a second angle to the stepwise surface,
wherein the first angle is an acute angle, and
wherein the second angle is an obtuse angle.

6. The semiconductor device of claim 1,
wherein a width of the first portion in a first direction parallel to a top surface of the substrate decreases as a distance from the substrate increases, and
wherein a width of the second portion in the first direction increases as a distance from the substrate increases.

7. The semiconductor device of claim 1, wherein a width of the uppermost portion of the first portion in a first direction parallel to a top surface of the substrate is smaller than a width of the lowermost portion of the second portion in the first direction.

8. The semiconductor device of claim 1,
wherein the data storage pattern comprises a bottom electrode, a magnetic tunnel junction pattern, and a top electrode sequentially stacked on the lower insulating layer, and
wherein the top electrode comprises a conductive metal nitride.

9. The semiconductor device of claim 8, wherein the conductive metal nitride is tantalum nitride.

10. A semiconductor device, comprising:
a lower insulating layer on a substrate;
a data storage pattern on the lower insulating layer;
a cell insulating layer disposed on the lower insulating layer to cover the data storage pattern;
a cell conductive line on the data storage pattern; and
a capping insulating layer interposed between a side surface of the data storage pattern and the cell insulating layer,
wherein the cell conductive line comprises a first portion adjacent to the data storage pattern and a second portion on the first portion,
wherein a width of the first portion in a first direction decreases as a distance from the substrate increases,
wherein a width of the second portion in the first direction increases as a distance from the substrate increases, and
wherein the first direction is parallel to a top surface of the substrate.

11. The semiconductor device of claim 10, wherein a width of the uppermost portion of the first portion in the first direction is equal to a width of the lowermost portion of the second portion in the first direction.

12. The semiconductor device of claim 10, wherein the cell conductive line further comprises a conductive barrier pattern enclosing the first portion and the second portion.

13. The semiconductor device of claim 12,
wherein the conductive barrier pattern has a first side surface in a region enclosing the first portion and has a second side surface in a region enclosing the second portion, and
wherein the capping insulating layer is extended to the first side surface.

14. The semiconductor device of claim 13,
wherein the capping insulating layer is extended to the second side surface, and
wherein the uppermost portion of the capping insulating layer is located at a height lower than a top surface of the cell insulating layer.

15. A semiconductor device, comprising:
a substrate including a cell region and a peripheral region;
a first lower insulating layer disposed on the cell region and extended to the peripheral region;
a second lower insulating layer disposed on the first lower insulating layer on the cell region and extended to the first lower insulating layer on the peripheral region;
data storage patterns disposed on the second lower insulating layer on the cell region and spaced apart from each other in a first direction and a second direction, which are parallel to a top surface of the substrate and are not parallel to each other;
cell conductive lines disposed on the data storage patterns, respectively, which are spaced apart from each other in the first direction;
a cell insulating layer disposed on the second lower insulating layer on the cell region to cover the data storage patterns;
a capping insulating layer interposed between a side surface of each of the data storage patterns and the cell insulating layer;
a peripheral insulating layer disposed on the second lower insulating layer on the peripheral region, the peripheral insulating layer comprising a material different from the cell insulating layer; and
a peripheral conductive contact disposed in the peripheral insulating layer to penetrate the first and second lower insulating layers on the peripheral region,
wherein each of the cell conductive lines comprises a first portion adjacent to each of the data storage patterns and a second portion on the first portion, and
wherein the capping insulating layer is extended to a side surface of the first portion.

16. The semiconductor device of claim 15,
wherein the side surface of the first portion is spaced apart from a side surface of the second portion in the first direction, and
wherein the second portion comprises a stepwise surface connecting the side surface of the first portion to the side surface of the second portion.

17. The semiconductor device of claim 16, wherein the uppermost surface of the capping insulating layer is in contact with the stepwise surface.

18. The semiconductor device of claim 16,
wherein the side surface of the first portion is inclined at a first angle to a bottom surface of the first portion,
wherein the side surface of the second portion is inclined at a second angle to the stepwise surface,
wherein the first angle is an acute angle, and
wherein the second angle is an obtuse angle.

19. The semiconductor device of claim 15, further comprising:
bottom electrode contacts provided to penetrate the first and second lower insulating layers on the cell region and connected to the data storage patterns, respectively; and
interconnection lines disposed between the substrate and the first lower insulating layer,
wherein the bottom electrode contacts and the peripheral conductive contact are provided to penetrate the first lower insulating layer and are connected to the interconnection lines.

20. The semiconductor device of claim 15, wherein a width of the uppermost portion of the first portion in the first direction is smaller than a width of the lowermost portion of the second portion in the first direction.
